(19) United States
(12) Patent Application Publication
(10) Pub. No.: US 2025/0106986 A1
(43) Pub. Date: Mar. 27, 2025

(54) STRETCHABLE WIRING BOARD

(71) Applicant: Murata Manufacturing Co., Ltd., Nagaokakyo-shi (JP)

(72) Inventors: Hayato KATSU, Nagaokakyo-shi (JP); Takayoshi OBATA, Nagaokakyo-shi (JP)

(21) Appl. No.: 18/973,337

(22) Filed: Dec. 9, 2024

Related U.S. Application Data
(63) Continuation of application No. PCT/JP2023/021507, filed on Jun. 9, 2023.

(30) Foreign Application Priority Data
Jun. 20, 2022 (JP) 2022-098928

(51) Int. Cl. H05K 1/02

(52) U.S. Cl. CPC H05K 1/0277; H05K 2201/0158

(57) ABSTRACT

A stretchable wiring board that includes: a stretchable substrate having a first main surface and a second main surface facing each other in a thickness direction; a wiring member on at least the first main surface side of the stretchable substrate and including at least one stretchable wiring extending in a plane direction including a length direction orthogonal to the thickness direction and a width direction orthogonal to the thickness direction and the length direction; a protective member covering at least one of the first main surface and the second main surface of the stretchable substrate; and a film member on at least one of the stretchable substrate side and a side opposite to the stretchable substrate with respect to the protective member, wherein the film member is constructed such that an appearance of the film member is irreversibly changed when the film member is stretched in the length direction.

### CROSS REFERENCE TO RELATED APPLICATIONS

The present application is a continuation of International application No. PCT/JP2023/021507, filed Jun. 9, 2023, which claims priority to Japanese Patent Application No. 2022-098928, filed Jun. 20, 2022, the entire contents of each of which are incorporated herein by reference.

### TECHNICAL FIELD

The present disclosure relates to a stretchable wiring board.

### BACKGROUND ART

Patent Document 1 discloses a code-shaped temperature fuse in which a linear fuse is arranged in an insulating coated tube, in which the linear fuse is bent in a shape having stretchability in a longitudinal direction of the linear fuse.
Patent Document 1: Japanese Patent Application Laid-Open No. 10-188756

### SUMMARY OF THE DISCLOSURE

In recent years, by acquiring and analyzing biological information (vital signs) by using a stretchable wiring board, a state of a human body and the like are managed. In a case where a stretchable wiring board is used in a state of being attached to a human body, for example, a wiring used for the stretchable wiring board is required to have stretchability that can follow movement of the human body. That is, a wiring used for a stretchable wiring board is required to be a stretchable wiring having stretchability.

However, if a wiring used for a stretchable wiring board is a stretchable wiring, when the stretchable wiring board is excessively stretched more than expected, resistance of the stretchable wiring is likely to increase along with the extension of the stretchable wiring board. When resistance of the stretchable wiring increases in this manner, in a case where excessive current flows through the stretchable wiring, there is a possibility that the stretchable wiring generates heat and is easily disconnected. Furthermore, when a stretchable wiring board is used in a state in which resistance of a stretchable wiring is high, there is a possibility that an error occurs in biological information to be acquired, or when excessive current flows through the stretchable wiring, heat is generated and an adverse effect, such as a burn, is caused on a human body.

On the other hand, by incorporating a fuse having stretchability such as the code-shaped temperature fuse described in Patent Document 1 into a stretchable wiring board, it is conceivable to have a mechanism in which the stretchable wiring board is electrically broken by blowing of the fuse when overcurrent flows through a stretchable wiring in a state in which the stretchable wiring board is excessively stretched more than expected. However, it is technically difficult to incorporate a code-shaped temperature fuse having a hollow structure described in FIG. 1 and the like of Patent Document 1 into a stretchable wiring board. If the code-shaped temperature fuse described in Patent Document 1 can be incorporated into a stretchable wiring board, the stretchable wiring board has high temperature when the code-shaped temperature fuse is blown, which may adversely affect a human body.

From the above, in a case where a stretchable wiring board is used in a state of being attached to a human body, a mechanism capable of safely detecting an excessively stretched state of the stretchable wiring board is required.

The present disclosure has been made to solve the above problem, and an object of the present disclosure is to provide a stretchable wiring board capable of safely detecting an excessively stretched state.

A stretchable wiring board of the present disclosure includes: a stretchable substrate having a first main surface and a second main surface facing each other in a thickness direction; a wiring member on at least the first main surface side of the stretchable substrate and including at least one stretchable wiring extending in a plane direction including a length direction orthogonal to the thickness direction and a width direction orthogonal to the thickness direction and the length direction; a protective member that covers at least one of the first main surface and the second main surface of the stretchable substrate; and a film member on at least one of the stretchable substrate side and a side opposite to the stretchable substrate with respect to the protective member, in which the film member is constructed such that an appearance of the film member is irreversibly changed when the film member is stretched in the length direction.

According to the present disclosure, it is possible to provide a stretchable wiring board capable of safely detecting an excessively stretched state.

### BRIEF EXPLANATION OF THE DRAWINGS

FIG. 1 is a schematic perspective view illustrating an example of a stretchable wiring board according to a first embodiment of the present disclosure.

FIG. 2 is a schematic plan view illustrating a state before a film member in FIG. 1 is stretched in a length direction.

FIG. 3 is a schematic plan view illustrating a state after the film member in FIG. 1 is stretched in the length direction.

FIG. 4 is a schematic perspective view illustrating an example of the stretchable wiring board according to a second embodiment of the present disclosure.

FIG. 5 is a schematic plan view illustrating a state before a film member in FIG. 4 is stretched in the length direction.

FIG. 6 is a schematic plan view illustrating a state after the film member in FIG. 4 is stretched in the length direction.

### DESCRIPTION OF THE PREFERRED EMBODIMENTS

Hereinafter, a stretchable wiring board of the present disclosure will be described. Note that the present disclosure is not limited to a configuration below, and may be modified as appropriate without departing from the gist of the present disclosure. The present disclosure also includes a combination of a plurality of preferred configurations described below.

It goes without saying that each of the embodiments illustrated below is an example, and partial replacement or combination of configurations illustrated in different embodiments is possible. In a second and subsequent embodiments, matters common to a first embodiment will not be described, and only a different point will be mainly described. In particular, the same operation and effect by the same configurations will not be sequentially mentioned for each embodiment.

Drawings shown below are schematic views, and dimensions, scales of aspect ratios, and the like may be different from those of actual products.

A stretchable wiring board of the present disclosure includes: a stretchable substrate having a first main surface and a second main surface facing each other in a thickness direction; a wiring member on at least the first main surface side of the stretchable substrate and including at least one stretchable wiring extending in a plane direction including a length direction orthogonal to the thickness direction and a width direction orthogonal to the thickness direction and the length direction; a protective member that covers at least one of the first main surface and the second main surface of the stretchable substrate; and a film member on at least one of the stretchable substrate side and a side opposite to the stretchable substrate with respect to the protective member, in which the film member is constructed such that an appearance of the film member is irreversibly changed when the film member is stretched in the length direction.

### First Embodiment

In the stretchable wiring board according to the first embodiment of the present disclosure, the film member changes from a transparent state to an opaque state when stretched in a length direction.

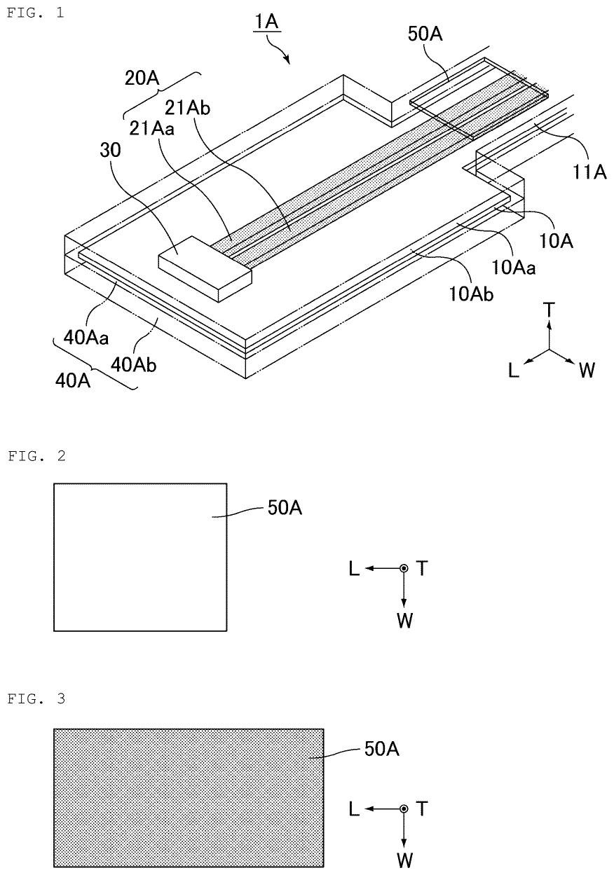

FIG. 1 is a schematic perspective view illustrating an example of the stretchable wiring board according to the first embodiment of the present disclosure.

A stretchable wiring board 1A illustrated in FIG. 1 includes a stretchable substrate 10A, a wiring member 20A, a protective member 40A, and a film member 50A.

In the present description, a length direction, a thickness direction, and a width direction are respectively defined as L, T, and W, as illustrated in FIG. 1 and the like. The length direction L, the thickness direction T, and the width direction W are orthogonal to each other. Further, a direction orthogonal to the thickness direction T and including the length direction L and the width direction W is defined as a plane direction.

In the present description, various dimensions in the length direction, the thickness direction, and the width direction are indicated as those in a state in which the stretchable wiring board is not stretched or contracted unless otherwise specified. Each of various dimensions in the length direction, the thickness direction, and the width direction is measured by viewing the stretchable wiring board in plan view or sectional view with an optical microscope.

The stretchable substrate 10A has a first main surface 10Aa and a second main surface 10Ab facing each other in the thickness direction T.

The stretchable substrate 10A has a narrow portion 11A having a smallest sectional area when a section orthogonal to the length direction L is viewed.

In the example shown in FIG. 1, a dimension in the thickness direction T of the stretchable substrate 10A is constant regardless of a position along the length direction L. That is, in the example shown in FIG. 1, the narrow portion 11A corresponds to a portion having a smallest dimension in the width direction W of the stretchable substrate 10A. Note that in a case where a dimension in the width direction W of the stretchable substrate 10A is constant regardless of a position along the length direction L, the narrow portion 11A corresponds to, for example, a portion having a smallest dimension in the thickness direction T of the stretchable substrate 10A.

The stretchable substrate 10A preferably contains at least one type of resin selected from a group including styrene-based resin, olefin-based resin, and silicone-based resin. Examples of the styrene-based resin include, for example, styrene-butadiene-styrene copolymer resin (SBS) and the like.

A dimension in the thickness direction T of the stretchable substrate 10A is preferably 100 μm or less, and more preferably 50 μm or less. As a dimension in the thickness direction T of the stretchable substrate 10A is in the above range, the stretchable wiring board 1A easily follows movement of a human body in a case where the stretchable wiring board 1A is used in a state of being attached to the human body.

A dimension in the thickness direction T of the stretchable substrate 10A is preferably 10 μm or more.

A breaking elongation rate in the length direction L of the stretchable substrate 10A is preferably 50% or more. In a case where a breaking elongation rate in the length direction L of the stretchable substrate 10A is in the above range, the stretchable wiring board 1A easily follows movement of a human body in a case where the stretchable wiring board 1A is used in a state of being attached to the human body.

From the viewpoint that the stretchable wiring board 1A easily follows movement of a human body, a breaking elongation rate in the length direction L of the stretchable substrate 10A is preferably as high as possible in a range of 50% or more.

Young's modulus of the stretchable substrate 10A is preferably 100 MPa or less, and more preferably 30 MPa or less. When Young's modulus of the stretchable substrate 10 is in the above range, the stretchable wiring board 1A is less likely to inhibit stretching and contraction of a surface of a human body in a case where the stretchable wiring board 1A is used in a state of being attached to the human body, so that discomfort due to the stretchable wiring board 1A is less likely to occur.

Young's modulus of the stretchable substrate 10A is preferably 3 MPa or more.

In the example shown in FIG. 1, a shape of the stretchable substrate 10A when viewed from the thickness direction T is a shape in which a dimension in the width direction W is larger than other portions at one end portion.

Note that a shape of the stretchable substrate 10A when viewed from the thickness direction T may be a shape in which a dimension in the width direction W is constant regardless of a position along the length direction L.

Further, a shape of the stretchable substrate 10A when viewed from the thickness direction T may be a shape in which one end portion is a loop shape, for example, a shape in which a linear portion and a loop-shaped portion are connected in the length direction L. In this case, the stretchable substrate 10A may have a narrow portion at a position where the linear portion and the loop-shaped portion are connected.

The wiring member 20A is provided on at least the first main surface 10Aa side of the stretchable substrate 10A.

In the example shown in FIG. 1, the wiring member 20A is provided on the first main surface 10Aa side of the stretchable substrate 10A.

Note that the wiring member 20A may be provided on the second main surface 10Ab side of the stretchable substrate 10A in addition to the first main surface 10Aa side of the stretchable substrate 10A.

In the example shown in FIG. 1, the wiring member 20A is provided on the first main surface 10Aa of the stretchable substrate 10A. That is, in the example shown in FIG. 1, the stretchable substrate 10A and the wiring member 20A are in contact with each other.

Note that another member may be interposed between the stretchable substrate 10A and the wiring member 20A.

The wiring member 20A includes at least one stretchable wiring extending in a plane direction including the length direction L and the width direction W.

In the example illustrated in FIG. 1, the wiring member 20A includes two stretchable wirings 21Aa and 21Ab extending in the plane direction.

Note that the wiring member 20A may include only one stretchable wiring, or may include three or more stretchable wirings.

A dimension in the thickness direction T of a stretchable wiring, and a dimension in the thickness direction T of the stretchable wiring 21Aa and the stretchable wiring 21Ab in the example illustrated in FIG. 1 are preferably 100 μm or less, and more preferably 50 μm or less. As a dimension in the thickness direction T of a stretchable wiring is in the above range, the stretchable wiring board 1A easily follows movement of a human body in a case where the stretchable wiring board 1A is used in a state of being attached to the human body.

A dimension in the thickness direction T of a stretchable wiring, and a dimension in the thickness direction T of the stretchable wiring 21Aa and the stretchable wiring 21Ab in the example illustrated in FIG. 1 are preferably 1 μm or more, and more preferably 10 μm or more.

The stretchable wiring, the stretchable wiring 21Aa and the stretchable wiring 21Ab in the example illustrated in FIG. 1 contain, for example, conductive particles and resin.

Examples of a constituent material of the conductive particles contained in the stretchable wiring include metal such as silver, copper, and nickel. Among them, silver is preferable from the viewpoint of achieving low resistance of the stretchable wiring.

An average particle diameter of the conductive particles is preferably 0.01 μm to 10 μm.

An average particle diameter of the conductive particles contained in the stretchable wiring is determined as described below. First, by polishing a stretchable wiring board or the like, a section in which a target stretchable wiring is exposed appears. Next, an image of the section is captured with a scanning electron microscope (SEM) or the like. Then, image analysis of the captured sectional image is performed to measure an equivalent circular diameter of the conductive particles contained in the stretchable wiring, and the obtained equivalent circular diameter is taken as a particle diameter of the conductive particles. After the above, number-based cumulative particle diameter distribution is determined from the obtained particle diameter of the conductive particles, and a particle diameter (median diameter D₅₀) at which cumulative probability is 50% in the number-based cumulative particle diameter distribution is determined as an average particle diameter of the conductive particles.

A shape of the conductive particles contained in the stretchable wiring is preferably spherical. A shape of the conductive particles contained in the stretchable wiring may be a flat shape, an irregular shape having a protrusion, or the like, in addition to a spherical shape, from the viewpoint of reducing a resistance change of the stretchable wiring against stretching and contraction.

In a case where the wiring member 20A includes a plurality of stretchable wirings, the conductive particles contained in each of the stretchable wirings are preferably the same at least in terms of a type of constituent material, but may be different from each other or may be different from each other in some parts.

Resin contained in the stretchable wiring is preferably at least one type of elastomer-based resin selected from a group consisting of epoxy-based resin, urethane-based resin, acrylic-based resin, and silicone-based resin. In this case, stretchability of the stretchable wiring is easily secured. Note that resin contained in the stretchable wiring may be resin other than the above as a stretchable function can be imparted.

In a case where the wiring member 20A includes a plurality of stretchable wirings, resin contained in each of the stretchable wirings is preferably the same at least in terms of type, but may be different from each other or may be different from each other in some parts.

The stretchable wiring, the stretchable wiring 21Aa and the stretchable wiring 21Ab in the example illustrated in FIG. 1 are formed, for example, as described below. First, conductive paste containing conductive particles and resin is applied to at least the first main surface 10Aa of the stretchable substrate 10A. Examples of a method of applying the conductive paste include a screen printing method, an inkjet method, and a dispensing method. Then, the applied conductive paste is heat-treated to form the stretchable wiring.

In the example shown in FIG. 1, each of the stretchable wiring 21Aa and the stretchable wiring 21Ab is electrically connected to an electronic component 30. That is, the stretchable wiring 21Aa and the stretchable wiring 21Ab constitute an electric path to the outside, that is, an electric path to the external electronic component 30 in the example illustrated in FIG. 1.

The electronic component 30 is mounted on each of the stretchable wiring 21Aa and the stretchable wiring 21Ab by a bonding member such as solder.

Examples of the electronic component 30 include a diode, an integrated circuit (IC), a capacitor, a resistor, an inductor, and an amplifier (operational amplifier, transistor, and the like).

The protective member 40A covers at least one of the first main surface 10Aa and the second main surface 10Ab of the stretchable substrate 10A.

In the example shown in FIG. 1, the protective member 40A covers both the first main surface 10Aa and the second main surface 10Ab of the stretchable substrate 10A.

Note that the protective member 40A may cover only the first main surface 10Aa of the stretchable substrate 10A, or may cover only the second main surface 10Ab of the stretchable substrate 10A.

In the example illustrated in FIG. 1, the protective member 40A includes a first protective portion 40Aa and a second protective portion 40Ab. In the example shown in FIG. 1, the first protective portion 40Aa covers the first main surface 10Aa of the stretchable substrate 10A, and the second protective portion 40Ab covers the second main surface 10Ab of the stretchable substrate 10A.

In the example illustrated in FIG. 1, the protective member 40A, more specifically, the first protective portion 40Aa covers the wiring member 20A and the electronic component 30 while covering the first main surface 10Aa of the stretchable substrate 10A. Since the protective member 40A covers the wiring member 20A and the electronic component 30, an effect below can be obtained.
The wiring member 20A and the electronic component 30 are protected from the outside.
Moisture resistance of the wiring member 20A and the electronic component 30 is improved.
Contact of a chemical substance used for the wiring member 20A and the electronic component 30 with a human body is prevented.
Electric leakage from the wiring member 20A and the electronic component 30 to a human body is prevented.

Examples of a constituent material of the protective member 40A and a constituent material of the first protective portion 40Aa and the second protective portion 40Ab in the example illustrated in FIG. 1 include polyvinyl chloride, polyethylene, polystyrene, polycarbonate, polyvinylidene fluoride, polyimide, a liquid crystal polymer, polytetrafluoroethylene, phenol resin, epoxy-based resin, urethane-based resin, acrylic-based resin, silicone-based resin, and elastomer-based resin such as styrene-butadiene resin.

The protective member 40A is formed, for example, by pressure-bonding a film containing the above-described material to at least one of the first main surface 10Aa and the second main surface 10Ab of the stretchable substrate 10A. Alternatively, the protective member 40A is formed, for example, by applying slurry containing the above-described material to at least one of the first main surface 10Aa and the second main surface 10Ab of the stretchable substrate 10A, and then subjecting the applied slurry to heat treatment or UV treatment. Examples of the method of applying the slurry include a screen printing method, an inkjet method, and a dispensing method.

The film member 50A is provided on at least one of the stretchable substrate 10A side and the side opposite to the stretchable substrate 10A with respect to the protective member 40A.

In the example shown in FIG. 1, the film member 50A is provided on the side opposite to the stretchable substrate 10A of the protective member 40A.

In the example shown in FIG. 1, the film member 50A is provided on the side opposite to the stretchable substrate 10A of the first protective portion 40Aa. In the example shown in FIG. 1, since the film member 50A is provided on the side opposite to the stretchable substrate 10A of the first protective portion 40Aa, a portion where the film member 50A is provided, that is, a portion where the first protective portion 40Aa and the film member 50A overlap each other is mechanically reinforced.

Note that the film member 50A may be provided on the side opposite to the stretchable substrate 10A of the second protective portion 40Ab.

Further, the film member 50A may be provided on both the side opposite to the stretchable substrate 10A of the first protective portion 40Aa and the side opposite to the stretchable substrate 10A of the second protective portion 40Ab.

In the example shown in FIG. 1, the film member 50A is provided on a main surface on the side opposite to the stretchable substrate 10A of the first protective portion 40Aa. That is, in the example shown in FIG. 1, the protective member 40A and the film member 50A are in contact with each other.

Note that another member may be interposed between the protective member 40A and the film member 50A.

Note that the film member 50A may be provided on the stretchable substrate 10A side of the protective member 40A. More specifically, the film member 50A may be provided only on the stretchable substrate 10A side of the first protective portion 40Aa, may be provided only on the stretchable substrate 10A side of the second protective portion 40Ab, or may be provided on both the stretchable substrate 10A side of the first protective portion 40Aa and the stretchable substrate 10A side of the second protective portion 40Ab.

Note that the film member 50A may be provided on both the stretchable substrate 10A side of the protective member 40A and the side opposite to the stretchable substrate 10A of the protective member 40A.

As described above, in the example shown in FIG. 1, each of the stretchable wiring 21Aa and the stretchable wiring 21Ab is electrically connected to the electronic component 30.

For example, in a case where a light emitting diode, which is a type of diode, is used as the electronic component 30, the stretchable wiring 21Aa and the stretchable wiring 21Ab function as drive wirings through which large current for driving the light emitting diode flows. In this case, when the stretchable wiring board 1A is excessively stretched in the length direction L, resistance of the stretchable wiring 21Aa and the stretchable wiring 21Ab becomes too high along with the stretching of the stretchable wiring 21Aa and the stretchable wiring 21Ab, by which there is a possibility that large current for driving the light emitting diode does not easily flow to the light emitting diode via the stretchable wiring 21Aa and the stretchable wiring 21Ab, the stretchable wiring 21Aa and the stretchable wiring 21Ab are easily disconnected when large current flows, or the stretchable wiring 21Aa and the stretchable wiring 21Ab easily generate heat when large current flows. As described above, when the stretchable wiring board 1A is excessively stretched in the length direction L, there is a possibility that a light emitting diode as the electronic component 30 is not turned on, or the stretchable wiring 21Aa and the stretchable wiring 21Ab excessively generate heat.

On the other hand, in the stretchable wiring board 1A, an appearance of the film member 50A changes irreversibly when stretched in the length direction L. In the stretchable wiring board 1A, by utilizing a fact that an appearance of the film member 50A irreversibly changes when stretched in the length direction L, it is possible to detect an excessively stretched state of the stretchable wiring board 1A in which the stretchable wiring board 1A is excessively stretched in the length direction L before occurrence of a trouble, such as that the stretchable wiring 21Aa and the stretchable wiring 21Ab are disconnected due to excessive stretching of the stretchable wiring 21Aa and the stretchable wiring 21Ab.

In the stretchable wiring board 1A, by providing the film member 50A as described above after grasping, in advance, an elongation rate of the film member 50A and a timing at which an appearance of the film member 50A changes, it is possible to adjust a timing at which an appearance of the film member 50A changes when the stretchable wiring board 1A is stretched in the length direction L, that is, a timing at which an excessively stretched state of the stretchable wiring board 1A is detected.

In the stretchable wiring board 1A, an appearance of the film member 50A is irreversibly changed when the film member 50A is stretched in the length direction L, so that it is possible to leave a trace that the stretchable wiring board 1A is excessively stretched in the length direction L. That is, from the stretchable wiring board 1A in which an appearance of the film member 50A is changed, it is possible to check a past history that the stretchable wiring board 1A has been excessively stretched in the length direction L.

Furthermore, when the stretchable wiring board 1A is used, it is possible to prompt the user to stop using the stretchable wiring board 1A at a time point at which an appearance of the film member 50A changes, that is, at a timing before the stretchable wiring 21Aa and the stretchable wiring 21Ab are excessively stretched in the length direction L. That is, when the stretchable wiring board 1A is used, it is possible to prompt the user to stop using the stretchable wiring board 1A before the stretchable wiring 21Aa and the stretchable wiring 21Ab excessively generate heat due to the stretchable wiring 21Aa and the stretchable wiring 21Ab being excessively stretched in the length direction L. For this reason, when the stretchable wiring board 1A is used, not only excessive heat generation of the stretchable wiring 21Aa and the stretchable wiring 21Ab, but also exposure of excessive heat generated in the stretchable wiring 21Aa and the stretchable wiring 21Ab to a body of the user are prevented, and as a result, safety is enhanced.

As described above, according to the stretchable wiring board 1A, it is possible to realize a stretchable wiring board capable of safely detecting an excessively stretched state.

In the present description, that an appearance of the film member is irreversibly changed when the film member is stretched in the length direction means that an appearance of the film member is changed when the film member is stretched in the length direction, and if the film member is contracted to a state before being stretched after being stretched in the length direction, the appearance does not return to the original one. The appearance of the film member includes a color, shape, and the like of the film member.

FIG. 2 is a schematic plan view illustrating a state before the film member in FIG. 1 is stretched in the length direction. FIG. 3 is a schematic plan view illustrating a state after the film member in FIG. 1 is stretched in the length direction.

The film member 50A shown in FIG. 2, which is in a state before being stretched in the length direction L, is in a transparent state. On the other hand, the film member 50A shown in FIG. 3, which is in a state after being stretched in the length direction L, is in an opaque state. As described above, the film member 50 changes from the transparent state to the opaque state when stretched in the length direction L. On the other hand, if the film member 50A is stretched in the length direction L and changes from the transparent state to the opaque state and then is contracted to the state before being stretched in the length direction L, the film member 50A does not change from the opaque state to the transparent state.

In the present description, that the film member changing from a transparent state to an opaque state means that when white light including a wavelength of 450 nm to 780 nm is transmitted through the film member, transmittance defined by Equation (1) below changes from a state of 95% or more to a state of 90% or less.

$$Transmittance ( \% ) = 100 \times transmitted light intensity / light source intensity \qquad ( 1 )$$

Hereinafter, an example of an aspect in which the film member 50A changes from the transparent state to the opaque state when being stretched in the length direction L will be described.

The film member 50A may be made from resin that changes from an amorphous state to a crystalline state when the film member 50A is stretched in the length direction L. In this case, since a molecular structure of resin constituting the film member 50A is in an amorphous state (also referred to as amorphous plastic) at a time point before the film member 50A is stretched in the length direction L, the film member 50A is in a transparent state that transmits light in a state before being stretched in the length direction L. On the other hand, since the molecular structure of the resin constituting the film member 50A is changed to a crystalline state (also referred to as crystalline plastic) as the film member 50A is stretched in the length direction L, the film member 50A becomes an opaque state that irregularly reflects light in a state after being stretched in the length direction L.

In the present description, that resin changes from an amorphous state to a crystalline state means that in a solidified state of the resin, a string-shaped polymer changes from an irregularly intertwined state to a regularly arranged state, and preferably degree of orientation of the resin changes from a state of 1% or less to a state of 20% or more. The degree of orientation of resin is calculated, for example, from a crystal peak of the resin measured by an X-ray diffraction method or the like.

In a case where the film member 50A is made from resin that changes from an amorphous state to a crystalline state when the film member 50A is stretched in the length direction L, a constituent material of the film member 50A is preferably polyethylene.

The film member 50A may include a microcapsule containing dye, which may be broken when the film member 50A is stretched in the length direction L. In this case, when the film member 50A is stretched in the length direction L, the microcapsule included in the film member 50A is broken and the dye seeps out, so that a color of the film member 50A is changed as a whole and an opaque state is obtained.

As described above, when the film member 50 is stretched in the length direction L and changes from the transparent state to the opaque state, a color as an example of an appearance irreversibly changes.

As described above, the narrow portion 11A corresponds to a portion of the stretchable substrate 10A, the portion having a smallest sectional area when a section orthogonal to the length direction L is viewed. For this reason, when the stretchable wiring board 1A is stretched in the length direction L, in the stretchable substrate 10A, stress tends to concentrate on the narrow portion 11A, and as a result, the narrow portion 11A tends to stretch more than other portions.

On the other hand, in the stretchable wiring board 1A, the film member 50A is provided at a position overlapping the narrow portion 11A when viewed from the thickness direction T. That is, in the stretchable wiring board 1A, the film member 50A whose appearance is irreversibly changed when stretched in the length direction L is provided in the narrow portion 11A that is most stretched when the stretchable substrate 10A is stretched in the length direction L. Therefore, according to the stretchable wiring board 1A in which the film member 50A is provided in the narrow portion 11A, when the film member 50A is stretched in the length direction L, an appearance of the film member 50A is more likely to change early as compared with a stretchable wiring board in which the film member 50A is not provided in the narrow portion 11A, so that an excessively stretched state can be detected earlier.

In the example shown in FIG. 1, the film member 50A is provided only at a position overlapping the narrow portion 11A when viewed from the thickness direction T.

Note that the film member 50A may be provided at a position not overlapping the narrow portion 11A when viewed in the thickness direction T, in addition to a position overlapping the narrow portion 11A when viewed in the thickness direction T.

Tensile strength in the length direction L of the film member 50A is preferably lower than tensile strength in the length direction L of the wiring member 20A. In this case, when the stretchable wiring board 1A is stretched in the length direction L, the film member 50A is broken at a time point before the wiring member 20A is disconnected due to excessive stretching of the wiring member 20A in the length direction L. By the above, when the film member 50A is stretched in the length direction L, not only a color as an example of an appearance but also a shape is irreversibly changed, so that it is easier to detect an excessively stretched state of the stretchable wiring board 1A.

Tensile strength in the length direction L of the protective member 40A and tensile strength in the length direction L of each of the first protective portion 40Aa and the second protective portion 40Ab in the example illustrated in FIG. 1 are preferably higher than tensile strength in the length direction L of the wiring member 20A. In this case, when the stretchable wiring board 1A is stretched in the length direction L, the protective member 40A is not broken before the wiring member 20A. That is, when the stretchable wiring board 1A is stretched in the length direction L, the protective member 40A is not broken at a time point at which the wiring member 20A is disconnected due to excessive stretching of the wiring member 20A in the length direction L. For this reason, when the stretchable wiring board 1A is used, it is possible to prompt the user to stop using the stretchable wiring board 1A at a time point at which it is detected on the film member 50A that the wiring member 20A is excessively stretched in the length direction L, that is, a time point before occurrence of a trouble, such as that a chemical substance used for the wiring member 20A and the electronic component 30 comes into contact with a human body or electric leakage from the wiring member 20A and the electronic component 30 to a human body, due to breakage of the protective member 40A. As a result, safety when using the stretchable wiring board 1A having the protective member 40A is enhanced.

A breaking elongation rate in the length direction L of the protective member 40A and a breaking elongation rate in the length direction L of each of the first protective portion 40Aa and the second protective portion 40Ab in the example illustrated in FIG. 1 are preferably 200% or more.

A breaking elongation rate in the length direction L of the protective member 40A and a breaking elongation rate in the length direction L of each of the first protective portion 40Aa and the second protective portion 40Ab in the example illustrated in FIG. 1 are preferably 800% or less.

The stretchable wiring board 1A may further include an electrode connected to at least one of the stretchable wiring 21Aa and the stretchable wiring 21Ab. The stretchable wiring board 1A can function as a sensor by being attached to a human body with such an electrode interposed therebetween. In this case, according to the stretchable wiring board 1A, for example, it is possible to detect an excessively stretched state before at least one of the stretchable wiring 21Aa and the stretchable wiring 21Ab connected to the electrode is excessively stretched in the length direction L and disconnected, that is, before abnormality of the sensor occurs. By the above, it is possible to prompt the user to stop using the stretchable wiring board 1A before abnormality of the sensor occurs, so that it is possible to prevent problems such as acquisition of erroneous biological information and diagnosis based on erroneous biological information.

The electrode is preferably a gel electrode. The stretchable wiring board 1 is easily attached to a human body by the gel electrode. The gel electrode includes, for example, a conductive gel material containing water, alcohol, a humectant, an electrolyte, and the like. Examples of such a gel material include hydrogel.

### Second Embodiment

In the stretchable wiring board according to a second embodiment of the present disclosure, the film member is provided with a cut that can be broken when the film member is stretched in the length direction. The stretchable wiring board according to the second embodiment of the present disclosure is the same as the stretchable wiring board according to the first embodiment of the present disclosure except for the above point.

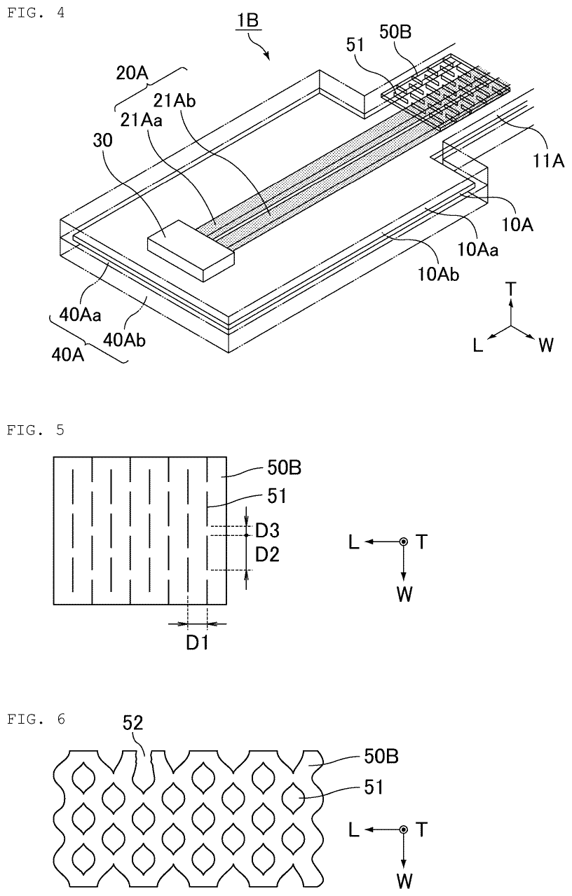

FIG. 4 is a schematic perspective view illustrating an example of the stretchable wiring board according to the second embodiment of the present disclosure.

A stretchable wiring board 1B illustrated in FIG. 4 includes the stretchable substrate 10A, the wiring member 20A, the protective member 40A, and a film member 50B. That is, the stretchable wiring board 1B is different from the stretchable wiring board 1A in including the film member 50B instead of the film member 50A.

FIG. 5 is a schematic plan view illustrating a state before the film member in FIG. 4 is stretched in the length direction. FIG. 6 is a schematic plan view illustrating a state after the film member in FIG. 4 is stretched in the length direction.

The film member 50B is provided with a cut 51 that can be broken when the film member 50B is stretched in the length direction L. In the film member 50B shown in FIG. 5, which is in a state before being stretched in the length direction L, the cut 51 is not broken. On the other hand, in the film member 50B shown in FIG. 6, which is in a state after being stretched in the length direction L, the cut 51 is broken at a broken portion 52. As described above, a shape of the film member 50B changes when the film member 50B is stretched in the length direction L. On the other hand, if the film member 50B is contracted to a state before being stretched in the length direction L after being stretched in the length direction L to change the shape, the shape does not return to the original shape since the cut 51 remains broken at the broken portion 52.

As described above, when the film member 50B is stretched in the length direction L, the shape as an example of an appearance irreversibly changes.

Therefore, according to the stretchable wiring board 1B, it is possible to realize a stretchable wiring board that allows safe detection of an excessively stretched state similarly to the stretchable wiring board 1A by utilizing the fact that an appearance of the film member 50B is irreversibly changed when the film member 50B is stretched in the length direction L.

Hereinafter, an example of an aspect in which a shape of the film member 50B is likely to change when the film member 50B is stretched in the length direction L will be described.

In the film member 50B, the cut 51 preferably extends along the width direction W.

In the stretchable wiring board 1B, a relationship between a dimension D2 in the width direction W of the cut 51 and a breaking elongation rate in the length direction L of the film member 50B until the cut 51 breaks is grasped in advance, and then, as described above, the cut 51 is provided along the width direction W, so that it is possible to adjust a timing at which an appearance of the film member 50B changes (the cut 51 breaks) when the stretchable wiring board 1B is stretched in the length direction L, that is, a timing at which an excessively stretched state of the stretchable wiring board 1B is detected.

In the stretchable wiring board 1B, a breaking elongation rate in the length direction L of the film member 50B until the cut 51 is broken can also be adjusted based on a distance D1 between the cuts 51 in the length direction L and a distance D3 between the cuts 51 in the width direction W in addition to the dimension D2 of the cut 51 in the width direction W. For example, when the distance D1 between the cuts 51 in the length direction L is shortened and the dimension D2 of the cuts 51 in the width direction W is lengthened, a breaking elongation rate in the length direction L of the film member 50B until the cut 51 is broken can be increased.

Note that, in the film member 50B, the cut 51 may be provided along a plane direction (for example, the length direction L) other than the width direction W.

In the film member 50B, a plurality of the cuts 51 are preferably provided. In this case, a plurality of the cuts 51 are preferably provided so as to be aligned in the same straight line along the width direction W. Further, a plurality of the cuts 51 are preferably provided such that rows of the cuts 51 arranged in the same straight line along the width direction W are arranged at intervals in the length direction L.

In the stretchable wiring board 1B, a relationship between the number, arrangement, and the like of the cuts 51 and a breaking elongation rate in the length direction L of the film member 50B until the cut 51 is broken is grasped in advance, and then the number, arrangement, and the like of the cuts 51 are set as described above, so that it is possible to adjust a timing at which an appearance of the film member 50B changes (the cut 51 is broken) when the stretchable wiring board 1B is elongated in the length direction L, that is, a timing at which an excessively stretched state of the stretchable wiring board 1B is detected.

Note that, in the film member 50B, only one of the cut 51 may be provided.

The film member 50B is preferably made from non-stretchable resin. In this case, when the film member 50B is stretched in the length direction L, the cut 51 is easily broken at an earlier stage, so that an appearance of the film member 50B is easily changed at an earlier stage.

In the present description, that resin is non-stretchable means that when target resin is molded into a resin film having a length of 18 mm, a width of 5 mm, and a thickness of 38 μm, tensile elastic modulus of the resin film in a length direction is 1 GPa or more.

In a case where the film member 50B is made from non-stretchable resin, a constituent material of the film member 50B is preferably at least one of polyethylene terephthalate and polyimide. That is, a constituent material of the film member 50B is preferably polyethylene terephthalate, more preferably polyimide, and still more preferably a mixture of polyethylene terephthalate and polyimide.

In each of the above embodiments, an aspect in which the stretchable wiring board is stretched in the length direction when the stretchable wiring board is used is described, but the stretchable wiring board may be stretched in a plane direction (for example, in the width direction) other than the length direction in addition to the length direction.

Content below is disclosed in the present description.

<1> A stretchable wiring board including: a stretchable substrate having a first main surface and a second main surface facing each other in a thickness direction; a wiring member on at least the first main surface side of the stretchable substrate and including at least one stretchable wiring extending in a plane direction including a length direction orthogonal to the thickness direction and a width direction orthogonal to the thickness direction and the length direction; a protective member that covers at least one of the first main surface and the second main surface of the stretchable substrate; and a film member on at least one of the stretchable substrate side and a side opposite to the stretchable substrate with respect to the protective member, in which the film member is constructed such that an appearance of the film member is irreversibly changed when the film member is stretched in the length direction.

<2> The stretchable wiring board according to <1>, in which the film member is constructed to change from a transparent state to an opaque state when stretched in the length direction.

<3> The stretchable wiring board according to <2>, in which the film member is made from resin that changes from an amorphous state to a crystalline state when the film member is stretched in the length direction.

<4> The stretchable wiring board according to <3>, in which a constituent material of the film member is polyethylene.

<5> The stretchable wiring board according to any of <1> to <4>, in which the film member includes a cut configured to be broken when stretched in the length direction.

<6> The stretchable wiring board according to <5>, in which the cut extends along the width direction.

<7> The stretchable wiring board according to <5> or <6>, in which the film member is made from non-stretchable resin.

<8> The stretchable wiring board according to <7>, in which a constituent material of the film member is at least one of polyethylene terephthalate and polyimide.

<9> The stretchable wiring board according to any of <1> to <8>, in which the stretchable substrate has a narrow portion having a smallest sectional area when a section orthogonal to the length direction is viewed, and the film member is at a position overlapping the narrow portion when viewed from the thickness direction.

<10> The stretchable wiring board according to any of <1> to <9>, in which the film member is on a side opposite to the stretchable substrate with respect to the protective member.

### DESCRIPTION OF REFERENCE SYMBOLS

1A, 1B: Stretchable wiring board
10A: Stretchable substrate
10Aa: First main surface
10Ab: Second main surface
11A: Narrow portion
20A: Wiring member
21Aa, 21Ab: Stretchable wiring
30: Electronic component
40A: Protective member
40Aa: First protective portion
40Ab: Second protective portion
50A, 50B: Film member
51: Cut
52: Broken portion
D1: Distance between cuts in length direction
D2: Dimension in width direction of cut
D3: Distance between cuts in width direction
L: Length direction
T: Thickness direction
W: Width direction

1. A stretchable wiring board comprising:
a stretchable substrate having a first main surface and a second main surface facing each other in a thickness direction;
a wiring member on at least the first main surface side of the stretchable substrate and including at least one stretchable wiring extending in a plane direction including a length direction orthogonal to the thickness direction and a width direction orthogonal to the thickness direction and the length direction;
a protective member that covers at least one of the first main surface and the second main surface of the stretchable substrate; and
a film member on at least one of the stretchable substrate side and a side opposite to the stretchable substrate with respect to the protective member,
wherein the film member is constructed such that an appearance of the film member is irreversibly changed when the film member is stretched in the length direction.

2. The stretchable wiring board according to claim 1, wherein the film member is constructed to change from a transparent state to an opaque state when stretched in the length direction.

3. The stretchable wiring board according to claim 2, wherein the film member is made from resin that changes from an amorphous state to a crystalline state when the film member is stretched in the length direction.

4. The stretchable wiring board according to claim 3, wherein a constituent material of the film member is polyethylene.

5. The stretchable wiring board according to claim 1, wherein a tensile strength in the length direction of the film member is lower than a tensile strength in the length direction of the wiring member.

6. The stretchable wiring board according to claim 1, wherein the film member includes a cut configured to be broken when stretched in the length direction.

7. The stretchable wiring board according to claim 6, wherein the cut extends along the width direction.

8. The stretchable wiring board according to claim 6, wherein the film member is made from non-stretchable resin.

9. The stretchable wiring board according to claim 8, wherein a constituent material of the film member is at least one of polyethylene terephthalate and polyimide.

10. The stretchable wiring board according to claim 1, wherein
the stretchable substrate has a narrow portion having a smallest sectional area when a section orthogonal to the length direction is viewed, and
the film member is at a position overlapping the narrow portion when viewed from the thickness direction.

11. The stretchable wiring board according to claim 10, wherein the film member is constructed to change from a transparent state to an opaque state when stretched in the length direction.

12. The stretchable wiring board according to claim 11, wherein the film member is made from resin that changes from an amorphous state to a crystalline state when the film member is stretched in the length direction.

13. The stretchable wiring board according to claim 12, wherein a constituent material of the film member is polyethylene.

14. The stretchable wiring board according to claim 10, wherein a tensile strength in the length direction of the film member is lower than a tensile strength in the length direction of the wiring member.

15. The stretchable wiring board according to claim 10, wherein the film member includes a cut configured to be broken when stretched in the length direction.

16. The stretchable wiring board according to claim 15, wherein the cut extends along the width direction.

17. The stretchable wiring board according to claim 15, wherein the film member is made from non-stretchable resin.

18. The stretchable wiring board according to claim 17, wherein a constituent material of the film member is at least one of polyethylene terephthalate and polyimide.

19. The stretchable wiring board according to claim 1, wherein the film member is on a side opposite to the stretchable substrate with respect to the protective member.
